(19) United States
(12) Patent Application Publication
(10) Pub. No.: US 2010/0188143 A1
(43) Pub. Date: Jul. 29, 2010

(54) Bias circuit, and gm-C filter circuit and semiconductor integrated circuit each including the same

(75) Inventor: Teisuke Kishikawa, Nagasaki (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 12/591,815

(22) Filed: Dec. 2, 2009

(30) Foreign Application Priority Data
Jan. 23, 2009 (JP) 2009-012589

(51) Int. Cl. H03K 5/00

(52) U.S. Cl. 327/553

(57) ABSTRACT

A bias circuit, includes: a first positive channel Metal Oxide Semiconductor transistor forming a first current source; a second positive channel Metal Oxide Semiconductor transistor composing a current mirror circuit of the first positive channel Metal Oxide Semiconductor transistor and forming a second current source; a first negative channel Metal Oxide Semiconductor transistor having a drain to which a current is supplied from the first current source; a second negative channel Metal Oxide Semiconductor transistor composing a current mirror circuit together with the first negative channel Metal Oxide Semiconductor transistor, and having a drain to which a current is supplied from the second current source; and a resistor connected between a source of the second negative channel Metal Oxide Semiconductor transistor and a ground; wherein a resistance component for gm adjustment is connected between a source of the first negative channel Metal Oxide Semiconductor transistor and the ground.

### BACKGROUND OF THE INVENTION

1. Field of the Invention

The present invention relates to a bias circuit, and a gm-C filter circuit and a semiconductor integrated circuit each including the same.

2. Description of the Related Art

A filter circuit for executing signal processing is extensively used in electronic apparatuses such as a wireless communication apparatus and an optical disc device. Miniaturization and speed-up are strongly demanded for such an electronic apparatus. Along with this strong request, the miniaturization and the speed-up are also demanded for the filter circuit.

A gm-C filter circuit composed of Operational Transconductance Amplifiers (OTAs) and capacitors is known as a filter circuit which is provided in order to realize the miniaturization and the speed-up.

For the purpose of suppressing a change in value of a transconductance gm caused by a change in temperature or change in power source voltage, as shown in FIG. 6, this gm-C filter circuit is provided with a bias circuit for maintaining gm of each of the OTAs in a gm-C filter portion.

FIG. 7 shows an existing configuration of a bias circuit 100 for a gm-C filter. This bias circuit 100 operates so that a product of a mobility (μn) of an electron in an NMOS (negative channel Metal Oxide Semiconductoe) transistor Q13, and a drain-to-source current I_{ds} of the NMOS transistor Q13 becomes constant.

In the figure, when a ratio of a current supplied from a current source I10 to the NMOS transistor Q13 to a current supplied from the current source I10 to an NMOS transistor Q14 is k:1, a transconductance gm1 of the NMOS transistor Q13 can be expressed by Expression (1):

$$gml = \frac{2 k}{R} ( 1 - \sqrt{\frac{( {W}_{1} / {L}_{1} )}{k ( {W}_{2} / {L}_{2} )}} ) \qquad ( 1 )$$

Where W₁ is a channel width of the NMOS transistor Q13, L₁ is a channel length of the NMOS transistor Q13, W₂ is a channel width of the NMOS transistor Q14, and L₂ is a channel length of the NMOS transistor Q14.

It is understood from Expression (1) that there is obtained a value of the transconductance gm1 which is independent of a manufacture dispersion of threshold independent of a manufacture dispersion of threshold voltages Vₜₕ of the NMOS transistors Q13, and changes in temperature and power source voltage.

However, the bias circuit 100 shown in FIG. 7 is an ideal circuit. Thus, a ratio of a drain current of the NMOS transistor Q13 to a drain current of the NMOS transistor Q14 is actually set in accordance with a current ratio in a current mirror circuit composed of PMOS (positive channel Metal Oxide Semiconductor) transistors Q11 and Q12.

In a bias circuit 200 shown in FIG. 8, mobilities (μn) of the electrons in the PMOS transistors Q11 and Q12 decrease with a rise in temperature. At this time, a drain-to-source voltage of the PMOS transistor Q12 increases equally to a gate-to-source voltage of the PMOS transistor Q12. On the other hand, however, although a gate-to-source voltage of the NMOS transistor Q13 increases along with an increase in gate-to-source voltage of the PMOS transistor Q11, a drain-to-source voltage of the PMOS transistor Q13 decreases.

Therefore, a ratio, k, of a drain-to-source current of the PMOS transistor Q11 to a drain-to-source current of the PMOS transistor Q12 decreases with a rise in temperature. As a result, as shown in FIG. 9, a transconductance gm1 of the NMOS transistor Q13 monotonically decreases with the rise in temperature.

It is also expected that a PMOS transistor is cascode-connected between the PMOS transistor Q11 and the NMOS transistor Q13, and a PMOS transistor is cascode-connected between the PMOS transistor Q12 and the NMOS transistor Q14. In this case, however, the phenomenon described above is merely lightened, and the situation stops short of solving the problem.

A bias circuit including a first voltage-to-current converting circuit, a resistor Rₑₓₜ, a second voltage-to-current converting circuit, a current-to-voltage converting circuit, and a feedback section, as shown in FIG. 10, is proposed as means for avoiding the phenomenon described above in Japanese Patent Laid-Open No. 2005-94091 (hereinafter referred to as Patent Document 1). In this case, the first voltage-to-current converting circuit converts a first reference voltage inputted thereto into a current to output the resulting current. The resistor Rₑₓₜ generates a voltage corresponding to the output current from the first voltage-to-current converting circuit. The second voltage-to-current converting circuit outputs a current corresponding to a voltage difference between the voltage developed across the resistor Rₑₓₜ, and a second reference voltage. The current-to-voltage converting circuit converts the output current from the second voltage-to-current converting circuit into a voltage to output the resulting voltage. Also, the feedback section changes an operating point of an input circuit which receives as its input the first reference voltage in the first voltage-to-current converting circuit in accordance with the output voltage from the current-to-voltage converting circuit until the voltage difference becomes absence.

### SUMMARY OF THE INVENTION

With the circuit described in Patent Document 1, the transconductance gm of a transistor M3 is expressed by a product of a reciprocal number of a resistance value of the resistor Rₑₓₜ, and (V2/V1), and thus can be precisely set.

However, the circuit described in Patent Document 1 involves a problem that at least two buffers need to be provided and so forth, and thus a mounting area largely increases.

A present embodiment has been made in order to solve the problems described above, and it is therefore desirable to provide a bias circuit which is capable of suppressing an influence caused by a change in temperature, and a manufacture dispersion of threshold voltages Vₜₕ, and a gm-C filter circuit and a semiconductor integrated circuit each including the same.

In order to attain the desire described above, according to an embodiment of the present invention, there is provided a bias circuit including: a first PMOS transistor forming a first current source; a second PMOS transistor composing a current mirror circuit of the first PMOS transistor and forming a second current source; a first NMOS transistor having a drain to which a current is supplied from the first current source; a second NMOS transistor composing a current mirror circuit together with the first NMOS transistor, and having a drain to which a current is supplied from the second current source; and a resistor connected between a source of the second NMOS transistor and a ground; in which a resistance component for gm adjustment is connected between a source of the first NMOS transistor and the ground.

According to another embodiment of the present invention, there is provided a gm-C filter circuit including: a gm-C filter portion; and a bias circuit configured to output a bias voltage to the gm-C filter portion; the bias circuit including: a first PMOS transistor forming a first current source; a second PMOS transistor composing a current mirror circuit of the first PMOS transistor and forming a second current source; a first NMOS transistor having a drain to which a current is supplied from the first current source; a second NMOS transistor composing a current mirror circuit together with the first NMOS transistor, and having a drain to which a current is supplied from the second current source; and a resistance connected between a source of the second NMOS transistor and a ground; in which a resistor component for gm adjustment is connected between a source of the first NMOS transistor and the ground, and the gm-C filter portion receives as its input a bias voltage at the drain of the first NMOS transistor.

According to still another embodiment of the present invention, there is provided a semiconductor integrated circuit including: a gm-C filter portion; and a bias circuit configured to output a bias voltage to the gm-C filter portion; the bias circuit including: a first PMOS transistor forming a first current source; a second PMOS transistor composing a current mirror circuit of the first PMOS transistor and forming a second current source; a first NMOS transistor having a drain to which a current is supplied from the first current source; a second NMOS transistor composing a current mirror circuit together with the first NMOS transistor, and having a drain to which a current is supplied from the second current source; and a resistor connected between a source of the second NMOS transistor and a ground; in which a connection terminal is provided for connection of a resistance component for gm adjustment between a source of the first NMOS transistor and the ground.

As set forth hereinabove, according to the present invention, it is possible to provide the bias circuit which is capable of suppressing the influence of the change in temperature and the manufacture dispersion, and the gm-C filter circuit and the semiconductor integrated circuit each including the same. Therefore, for example, the highly precise gm-C filter circuit which is capable of setting a desired cut-off frequency can be provided with a smaller mounting area than that in an existing art. In addition, since it is unnecessary to provide a differential amplifier used to compose a general operational amplifier, the operation is also possible at a lower voltage (for example, a power source voltage of 1 V or less) than that in the differential amplifier.

### BRIEF DESCRIPTION OF THE DRAWINGS

FIG. 1 is a circuit diagram showing a configuration of a gm-C filter circuit including a bias circuit according to an embodiment of the present invention;

FIG. 2 is a circuit diagram showing a configuration of the gm-C filter circuit including the bias circuit according to the embodiment of the present invention;

FIG. 3 is a circuit diagram showing a configuration of the bias circuit according to the embodiment of the present invention;

FIG. 4 is a graph representing characteristics of the bias circuit according to the embodiment of the present invention;

FIG. 5 is a circuit diagram showing a configuration of a change of the bias circuit according to the embodiment of the present invention;

FIG. 6 is a circuit diagram showing a configuration of an existing gm-C filter circuit;

FIG. 7 is a circuit diagram showing a configuration of an existing bias circuit;

FIG. 8 is a circuit diagram showing a configuration of an existing bias circuit;

FIG. 9 is a graph representing characteristics of the existing bias circuit; and

FIG. 10 is a circuit diagram showing a configuration of an existing bias circuit.

### DETAILED DESCRIPTION OF THE PREFERRED EMBODIMENTS

A gm-C filter circuit according to an embodiment of the present invention is formed within a semiconductor integrated circuit (IC). Also, the gm-C filter circuit is highly precise filter circuit which can suppress an influence of a change in temperature and a manufacture dispersion, and thus can set a desired cut-off frequency. Thus, miniaturization and speed-up are realized for the gm-C filter circuit.

The gm-C filter circuit has a gm-C filter portion composed of Operational Transconductance Amplifiers (OTAs) and capacitors.

In addition, the gm-C filter circuit is provided with a bias circuit for maintaining a transconductance gm of each of the OTAs in the gm-C filter portion.

The bias circuit includes a first PMOS transistor forming a first current source, and a second PMOS transistor composing a current mirror circuit of the first PMOS transistor and forming a second current source.

In addition, the bias circuit includes a first NMOS transistor having a drain terminal to which a current is supplied from a first current source, and a second NMOS transistor composing a current mirror circuit together with the first NMOS transistor, and having a drain terminal to which a current is supplied from a second current source.

Also, the bias circuit includes a resistor connected between a source terminal of the first NMOS transistor and the ground.

Moreover, the bias circuit includes a resistance component for gm adjustment which is connected between a source terminal of the second NMOS transistor and the ground.

By providing the resistance component for gm adjustment in such a manner, it is possible to provide the bias circuit for which the influence of the change in temperature and the manufacture dispersion is suppressed.

Therefore, for example, by using the bias circuit, the highly precise gm-C filter circuit can be provided with a smaller mounting area than that in the existing art. In addition, since it is unnecessary to provide a differential amplifier used to configure a general operational amplifier, the operation is also possible at a lower voltage (for example, a power source voltage of 1 V or less) than that in the general operational amplifier.

Hereinafter, a bias circuit according to an embodiment of the present invention, and a gm-C filter circuit including the same will be concretely described.

1. gm-C Filter Circuit

Concrete configurations of the bias filter and the gm-C filter circuit including the same will be described in detail hereinafter with reference to the accompanying drawings.

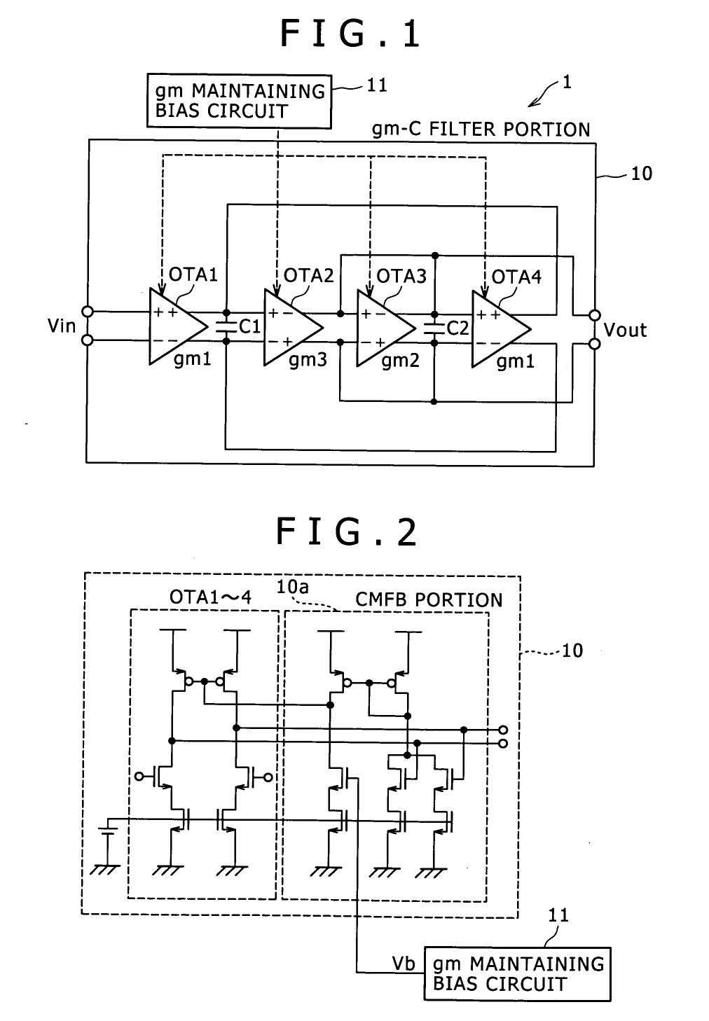

Firstly, the concrete configuration of the gm-C filter circuit will be described with reference to FIG. 1. FIGS. 1 and 2 are respectively circuit diagrams each showing a configuration of the gm-C filter circuit including the bias circuit of the embodiment.

As shown in FIG. 1, the gm-C filter circuit 1 including the bias circuit of the embodiment is composed of a gm-C filter portion 10, and a bias circuit 11.

The gm-C filter portion 10 is a filter circuit which can set a desired cut-off frequency, and is a composed of an OTA1 to an OTA4, and capacitors C1 and C2. It is noted that transconductances of the OTA1, the OTA2, the OTA3, and the OTA4 are represented by gm1, gm3, gm2, and gm1, respectively.

An input signal Vᵢₙ is inputted across input terminals (+, −) of the OTA1, and is amplified by the OTA1 to be outputted through output terminals (+, −) of the OTA1. The output (+, −) from the OTA1 is inputted across input terminals (+, −) of the OTA2, and is amplified by the OTA2 to be outputted in the form of an output signal Vₒᵤₜ through output terminals (+, −) of the OTA2.

The output signal Vₒᵤₜ outputted through the output terminals (+, −) of the OTA2 is applied across the capacitor C2, and is then inputted across input terminals (+, −) of the OTA3, input terminals (−, +) of the OTA4, and output terminals (+, −) of the OTA3. In addition, the output terminals (+, −) of the OTA4 are connected between the opposite terminals of the capacitor C1, and between the input terminals (+, −) of the OTA2.

By configuring the gm-C filter circuit 1 in such a manner, the gm-C filter circuit 1 becomes a second-order low pass filter (LPS) having the following characteristics expressed by. Expressions (2) to (4):

$$\begin{matrix}{V}_{out} = \frac{\frac{{gm}_{1} {gm}_{3}}{C}}{{s}^{2} + s \frac{{gm}_{2}}{C} + \frac{{gm}_{1} {gm}_{3}}{C}} {v}_{m} & ( 2 ) \\ {ω}_{o} = \frac{\sqrt{{gm}_{1} {gm}_{3}}}{C} & ( 3 ) \\ Q = \frac{\sqrt{{gm}_{1} {gm}_{3}}}{{gm}_{2}} & ( 4 )\end{matrix}$$

where ω₀ is a cut-off frequency of the gm-C filter circuit 1, and Q is a quality factor of the gm-C filter circuit 1.

As shown in FIG. 2, the gm-C filter portion 10 is provided with a CMFB portion 10a for determining a bias voltage for the output signal from the gm-C filter portion 10. Also, the transconductances gm1, gm3, gm2, and gm1 of the OTA1, the OTA2, the OTA3, and OTA4 are precisely adjusted in accordance with an output bias voltage V_{b} inputted from the bias circuit 11 to the CMFB portion 10a.

In the existing bias circuit, however, the change in power source voltage, the dispersion of the threshold voltage Vₜₕ, and the like result in a change in output bias voltage V_{b}. In order to cope with this situation, in the bias circuit 11 of the embodiment, the influence of the change in temperature, and the manufacture dispersion of the threshold voltages Vₜₕ is suppressed.

### 2. Bias Circuit

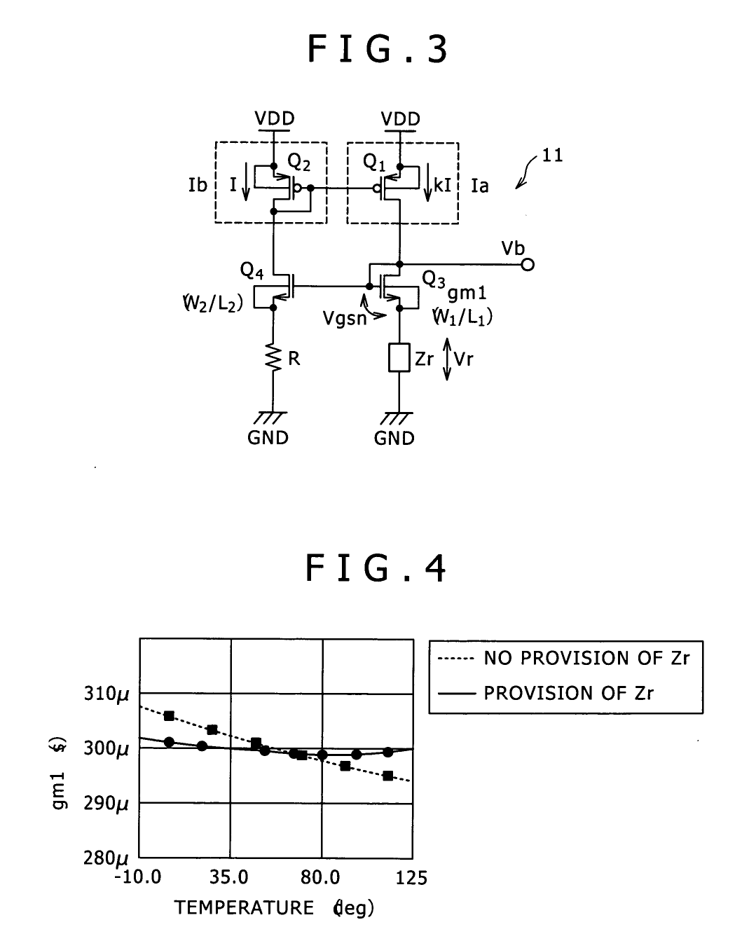

Next, the configuration and characteristics of the bias circuit 11 described above will be concretely described. FIG. 3 is a circuit diagram showing the configuration of the bias circuit of the embodiment, and FIG. 4 is a graph representing the characteristics of the bias circuit of the embodiment.

As shown in FIG. 3, the bias circuit 11 of the embodiment includes a first current source Iₐ and a second current source I_{b}. A ratio of a current of the first current source Iₐ to a current of the second current source I_{b} is k:1.

The first current source Iₐ is a current source for supplying a current having a current value KI, and is composed of a first PMOS transistor Q1. Each of a source terminal and a back gate terminal of the first PMOS transistor Q1 is connected to a power source VDD.

The second current source I_{b} is a current source for supplying a current having a current value I, and is composed of a second PMOS transistor Q2. In this case, each of a gate terminal and a drain terminal of the second PMOS transistor Q2 is connected to a gate terminal of the first PMOS transistor Q1, thereby composing a current mirror circuit. In addition, each of a source terminal and a back gate terminal of the second PMOS transistor Q2 is connected to the power source VDD.

In the bias circuit 11, currents are supplied from the first current source Iₐ and the second current source I_{b} to drain terminals of first and second NMOS transistors Q3 and Q4, respectively. That is to say, the drain terminal of the first PMOS transistor Q1 as the first current source Iₐ, and a drain terminal of the first NMOS transistor Q3 are connected to each other. In addition, the drain terminal of the second PMOS transistor Q2 as the second current source I_{b}, and a drain terminal of the second NMOS transistor Q4 are connected to each other. Also, a drain current of the first NMOS transistor Q3 is supplied from the first current source Iₐ, and a drain current of the second NMOS transistor Q4 is supplied from the second current source I_{b}.

A gate terminal of the second NMOS transistor Q4 is connected to each of a gate terminal and the drain terminal of the first NMOS transistor Q3. Thus, the first and second NMOS transistors Q3 and Q4 compose a current mirror circuit together with each other.

In addition, a resistor R is connected between the source terminal of the second NMOS transistor Q4 and the ground GND.

With the configuration described above, the bias circuit 11 operates so that a product of a mobility (μn) of an electron in the first NMOS transistor Q3, and a current value of a drain-to-source current of the first NMOS transistor Q3 becomes constant, thereby outputting the bias voltage V_{b}.

However, the ratio, k, of the drain-to-source current of the first PMOS transistor Q1 to the drain-to-source current of the second PMOS transistor Q2 decreases with a rise in temperature. As a result, the transconductance gm1 of the first NMOS transistor Q3 monotonically decreases with the rise in temperature.

In order to cope with this situation, in the bias circuit 11 of the embodiment, the source terminal of the first NMOS transistor Q3 is connected to the ground GND through a resistance component Zᵣ instead of connecting the source terminal of the first NMOS transistor Q3 to the ground GND as with the existing bias circuit.

It is noted that the resistance component Zᵣ may be composed of either a resistor or an NMOS transistor which operates in a triode region.

Here, when a composite transconductance between the third transistor Q3 and the resistance component Zᵣ connected in series with each other is gmt, the composite transconductance gmt can be expressed by Expression (5):

$$gmt = \frac{gml}{1 + gml \times Zr} \qquad ( 5 )$$

where gm1 is a transconductance of the third transistor Q3.

Therefore, the resistance component Zᵣ is set so that a decreasing rate of the transconductance gm1 following the rise in temperature, and a decreasing rate of {1+(gm1×Zᵣ)} become equal to each other. As a result, as shown in FIG. 4, the influence exerted on the value of the composite transconductance gmt by the change in temperature is suppressed.

As described above, in the bias circuit 11, the resistance component Zᵣ is provided, so that a voltage Vᵣ is developed across the source terminal of the first NMOS transistor Q3, and the ground GND. As a result, the decrease in transconductance gm1 caused by the rise in temperature, or the like is offset with the voltage Vᵣ thus developed.

In addition, when the back gate terminal of the first NMOS transistor Q3 is connected to the ground GND, a source-to-back gate voltage V_{sb} is developed across the source terminal and back gate terminal of the first NMOS transistor Q3, and thus the threshold voltage Vₜₕ changes. At this time, however, the provision of the resistance component Zᵣ makes it possible to suppress the temperature dependency of the composite transconductance gmt, and thus the resistance component Zᵣ becomes an effective section configured to suppress the temperature dependency of the composite transconductance gmt.

It should be noted that either a channel width or channel length of each of the first and second PMOS transistors Q1 and Q2, and the first and second NMOS transistors Q3 and Q4 can be given a variable range, and thus the composite transconductance gmt can be given an adjustment range.

In addition, since there is generally the dispersion of at least 10% in the resistance values of the resistors formed within the semiconductor integrated circuit (IC), it is preferable to provide the resistor R outside the semiconductor integrated circuit.

As has been described, in the bias circuit 11 of the embodiment, the resistance component Zᵣ is provided between the source terminal of the first NMOS transistor Q3, and the ground GND, thereby suppressing the temperature dependency of the composite transconductance gmt in the bias circuit 11.

Therefore, the highly precise gm-C filter circuit which can set the desired cut-off frequency can be provided with the smaller mounting area than that in the existing art.

In addition, since it is unnecessary to provide the differential amplifier used to configure the general operational amplifier, the operation is also possible at the lower voltage (for example, the power source voltage of 1 V or less) than that in the general operational amplifier.

### 3. Change

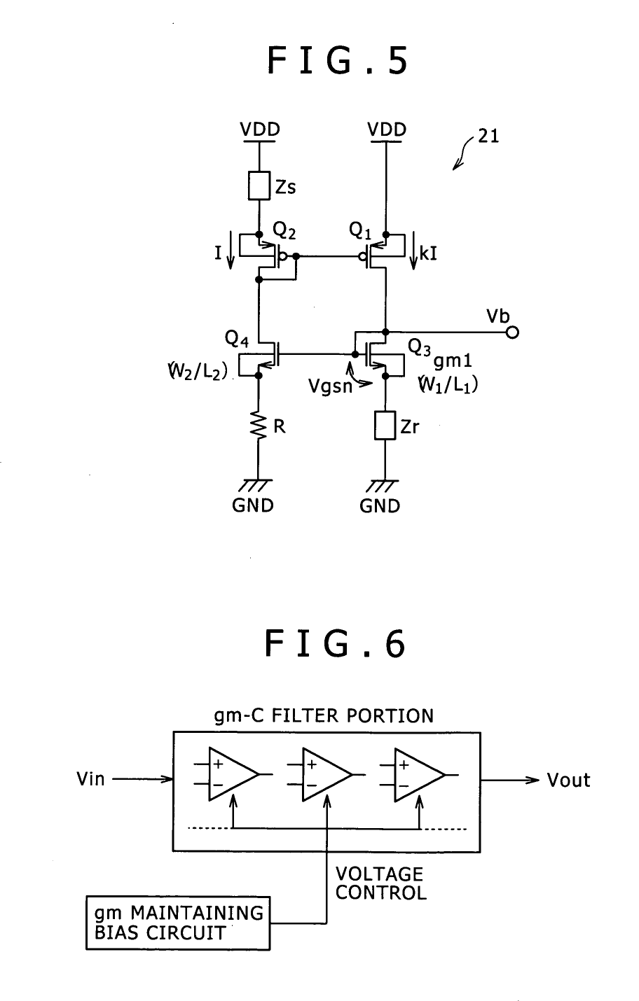

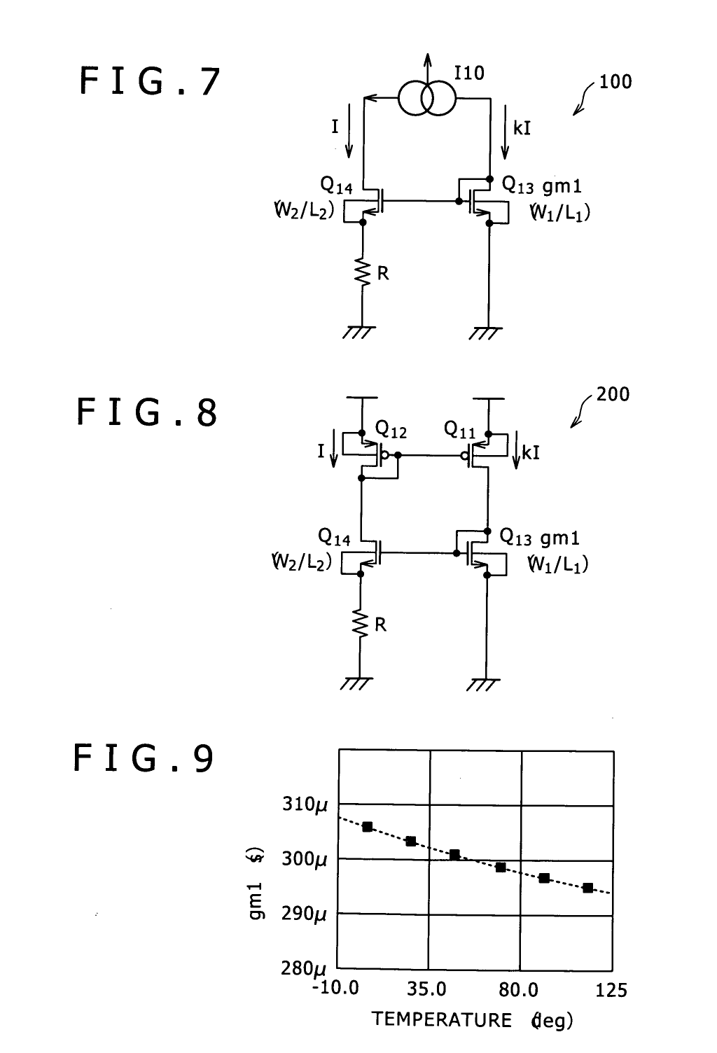

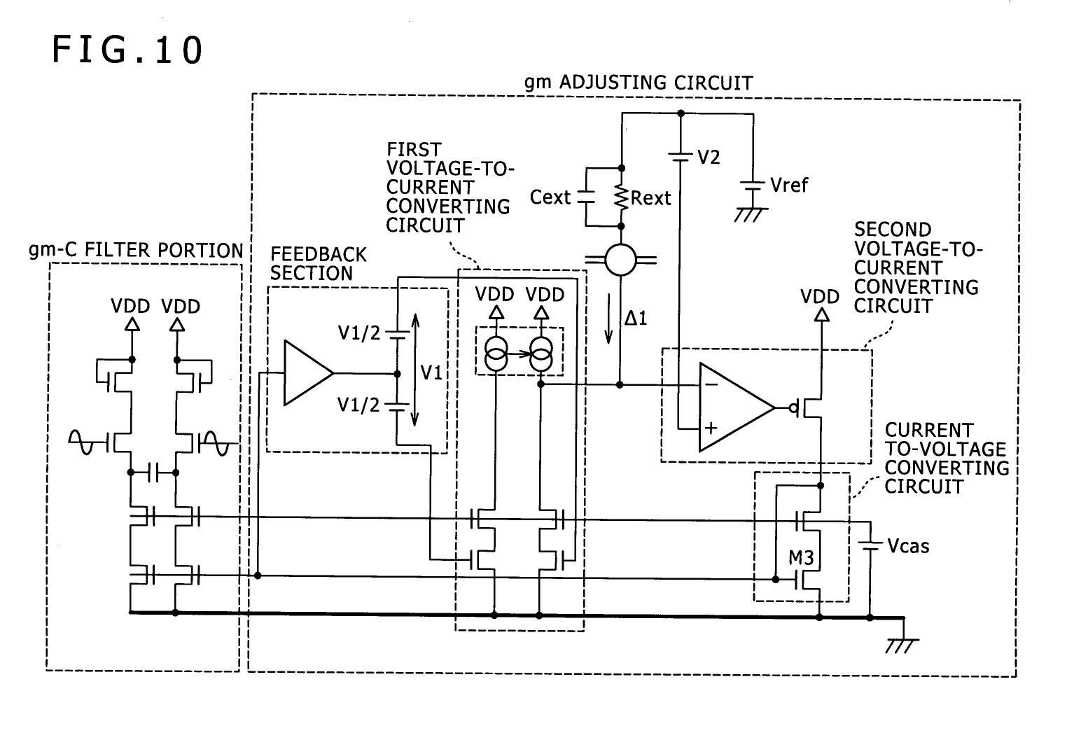

Next, a change of the bias circuit of the embodiment will be described. FIG. 5 is a circuit diagram showing a configuration of the change of the bias circuit of the embodiment. It is noted that the same constituent elements as those in the bias circuit 11 shown in FIG. 3 are designated with the same reference symbols, respectively, and a description thereof is omitted here for the sake of simplicity.

The bias circuit 21 shown in FIG. 5 is a bias circuit in which in addition to the resistance component Zᵣ in the configuration of the bias circuit 11 shown in FIG. 3, a second resistance component Zₛ is provided between the source terminal of the second PMOS transistor Zᵣ, and the power source VDD.

In addition to the resistance component Zᵣ, the second resistance component Zₛ is provided in such a manner, thereby making it possible to further suppress the temperature dependency of the transconductance component gmt.

### 4. Semiconductor Integrated Circuit

The semiconductor integrated circuit according to an embodiment of the present invention includes the gm-C filter portion 10, and the bias circuit 11 for outputting the bias voltage to the gm-C filter portion 10. In this case, the bias circuit 11 includes the first PMOS transistor Q1 forming the first current source Iₐ, the second PMOS transistor Q2 composing the current mirror of the first PMOS transistor Q1 and forming the second current source I_{b}, the first NMOS transistor Q3 having the drain terminal to which the current is supplied from the first current source Iₐ, the second NMOS transistor Q4 composing the current mirror circuit together with the first NMOS transistor Q3, and having the drain terminal to which the current is supplied from the second current source I_{b}, and the resistor R connected between the source terminal of the second NMOS transistor Q4 and the ground GND. In this case, a connection terminal is provided for connection of the resistance component Zᵣ for gm adjustment between the source terminal of the first NMOS transistor Q3 and the ground GND.

Although the embodiments of the present invention has been concretely described so far, the present invention is by no means limited to the embodiments described above, and thus various changes based on the technical idea of the present invention can be made.

The present application contains subject matter related to that disclosed in Japanese Priority Patent Application JP 2009-012589 filed in the Japan Patent Office on Jan. 23, 2009, the entire content of which is hereby incorporated by reference.

What is claimed is:

1. A bias circuit, comprising:
a first positive channel Metal Oxide Semiconductor transistor forming a first current source;
a second positive channel Metal Oxide Semiconductor transistor composing a current mirror circuit of said first positive channel Metal Oxide Semiconductor transistor and forming a second current source;
a first negative channel Metal Oxide Semiconductor transistor having a drain to which a current is supplied from said first current source;
a second negative channel Metal Oxide Semiconductor transistor composing a current mirror circuit together with said first negative channel Metal Oxide Semiconductor transistor, and having a drain to which a current is supplied from said second current source; and
a resistor connected between a source of said second negative channel Metal Oxide Semiconductor transistor and a ground;
wherein a resistance component for gm adjustment is connected between a source of said first negative channel Metal Oxide Semiconductor transistor and the ground.

2. The bias circuit according to claim 1, wherein said resistance component for gm adjustment is composed of a Metal Oxide Semiconductor transistor which operates in a triode region.

3. The bias circuit according to claim 1, wherein a second resistance component for gm adjustment is connected between a source of said positive channel Metal Oxide Semiconductor transistor, and a power source.

4. A gm-C filter circuit, comprising:
a gm-C filter portion; and
a bias circuit configured to output a bias voltage to said gm-C filter portion;
said bias circuit including
a first positive channel Metal Oxide Semiconductor transistor forming a first current source,
a second positive channel Metal Oxide Semiconductor transistor composing a current mirror of said first positive channel Metal Oxide Semiconductor transistor and forming a second current source,
a first negative channel Metal Oxide Semiconductor transistor having a drain to which a current is supplied from said first current source,
a second negative channel Metal Oxide Semiconductor transistor composing a current mirror circuit together with said first negative channel Metal Oxide Semiconductor transistor, and having a drain to which a current is supplied from said second current source, and
a resistor connected between a source of said second negative channel Metal Oxide Semiconductor transistor and a ground,
wherein a resistance component for gm adjustment is connected between a source of said first negative channel Metal Oxide Semiconductor transistor and said ground, and
said gm-C filter portion receives as its input a bias voltage at said drain of said first negative channel Metal Oxide Semiconductor transistor.

5. A semiconductor integrated circuit, comprising:
a gm-C filter portion; and
a bias circuit configured to output a bias voltage to said gm-C filter portion;
said bias circuit including
a first positive channel Metal Oxide Semiconductor transistor forming a first current source,
a second positive channel Metal Oxide Semiconductor transistor composing a current mirror circuit of said first positive channel Metal Oxide Semiconductor transistor and forming a second current source,
a first negative channel Metal Oxide Semiconductor transistor having a drain to which a current is supplied from said first current source,
a second negative channel Metal Oxide Semiconductor transistor composing a current mirror circuit together with said first negative channel Metal Oxide Semiconductor transistor, and having a drain to which a current is supplied from said second current source, and
a resistor connected between a source of said second negative channel Metal Oxide Semiconductor transistor and a ground,
wherein a connection terminal is provided for connection of a resistance component for gm adjustment between a source of said first negative channel Metal Oxide Semiconductor transistor and said ground.
